(19) United States
(12) Patent Application Publication
(10) Pub. No.: US 2026/0280398 A1
(43) Pub. Date: Sep. 17, 2026

(54) Magnetic Resonance-Compatible Stepper Motor for use in a Magnetic Resonance Apparatus with a Brake Unit

(71) Applicant: Siemens Healthineers AG, Forchheim (DE)

(72) Inventors: Johann Sukkau, Herzogenaurach (DE); Jakob Grün, Gössweinstein (DE)

(73) Assignee: Siemens Healthineers AG, Forchheim (DE)

(21) Appl. No.: 19/567,462

(22) Filed: Mar. 16, 2026

(30) Foreign Application Priority Data
Mar. 17, 2025 (DE) 10 2025 110 143.4

(51) Int. Cl. H02K 37/24; G01R 33/30; H02K 7/102

(52) U.S. Cl. CPC H02K 37/24; G01R 33/307; H02K 7/102

(57) ABSTRACT

The disclosure relates to a magnetic resonance-compatible stepper motor for use in a medical magnetic resonance apparatus, configured to implement a dominant or stray component of a basic magnetic field of the magnetic resonance apparatus as a stator. The magnetic resonance-compatible stepper motor also comprises a drive shaft, and at least two rotatably mounted motor coil elements for generating a drive torque of the stepper motor. The drive torque is transmissible by means of the drive shaft, and the stepper motor has a brake unit which is designed to lock a position of the drive shaft.

### CROSS-REFERENCE TO RELATED APPLICATIONS

This application claims priority to Germany application no. DE 10 2025 110 143.4, filed on Mar. 17, 2025, the contents of which are incorporated herein by reference in its entirety.

### TECHNICAL FIELD

The present disclosure relates to a magnetic resonance-compatible stepper motor for use in a medical magnetic resonance apparatus. The magnetic resonance-compatible stepper motor comprises a stator formed via action of a dominant component of a basic magnetic field of the magnetic resonance apparatus. The magnetic resonance-compatible stepper motor also comprises a drive shaft and at least two rotatably mounted motor coil elements for generating a drive torque of the stepper motor, the drive torque being transmissible by means of the drive shaft. Furthermore, the present disclosure is based on a magnetic resonance apparatus with a magnetic resonance-compatible stepper motor.

### BACKGROUND

If motor-driven movements and/or changes in position are performed within a magnetic resonance apparatus, a magnetic resonance-compatible drive unit is required to prevent interaction with the magnetic resonance examination. If the magnetic resonance-compatible drive unit includes a pneumatic unit, interaction with the magnetic resonance examination can be advantageously prevented. However, pneumatic feeds, in particular hoses, which can easily be crushed and can be very loud during operation, are required to generate and/or supply drive torque and/or movement torque.

Other magnetic resonance-compatible drive units include magnetic resonance-compatible stepper motors. Such magnetic resonance-compatible stepper motors comprise, for example, a stator, which is surrounded by the dominant components of the basic magnetic field of the magnetic resonance apparatus. In addition, such magnetic resonance-compatible stepper motors have one or more coil elements, which are preferably wound with copper wire. When an electric current flows through the coil element, which is arranged within the magnetic resonance apparatus and/or within an effective range of the basic magnetic field, a Lorentz force acts on the coil element, causing a movement of the coil element. However, the disadvantage of such stepper motors is that current must continue to flow through at least one coil element to lock a position. This can, however, lead to interference and/or impairment of a magnetic resonance examination. Such a stepper motor is known, for example, from U.S. Pat. No. 11,650,275.

### SUMMARY

The object of the present disclosure is to provide a stepper motor for use in a medical magnetic resonance apparatus, in which the stepper motor enables the fixing and/or locking of a position. The object is achieved by the embodiments as further described herein, including the claims.

The disclosure relates to a magnetic resonance-compatible stepper motor for use in a medical magnetic resonance apparatus, comprising (i) a stator, the stator comprising a dominant component of a basic magnetic field of the magnetic resonance apparatus, (ii) a drive shaft, and (iii) at least two rotatably mounted motor coil elements for generating a drive torque of the stepper motor, the drive torque being transmissible by means of the drive shaft. It is proposed that the magnetic resonance-compatible stepper motor has a brake unit which is designed to lock a position of the drive shaft.

The magnetic resonance apparatus may e.g. comprise a medical and/or diagnostic magnetic resonance apparatus, which is construed and/or designed to capture medical and/or diagnostic image data, e.g. medical and/or diagnostic magnetic resonance image data, of a patient. The magnetic resonance apparatus comprises a scanner unit formed by a magnet unit for capturing the medical and/or diagnostic image data. In an embodiment, the scanner unit, e.g. the magnet unit, comprises a basic magnet, a gradient coil unit, and a high-frequency (e.g. radio frequency (RF)) antenna unit.

The basic magnet is designed to generate a homogenous basic magnetic field. For instance, the basic magnet is designed to generate a strong and constant basic magnetic field. The homogenous basic magnetic field may e.g. be arranged and/or located within a patient reception area of the magnetic resonance apparatus. The patient reception area is construed and/or designed to receive the patient, e.g. the area of the patient to be examined, for a medical magnetic resonance examination. For example, the patient reception area may be cylindrical in shape and/or surrounded by the scanner unit, e.g. the magnet unit, in a cylindrical manner.

Within the patient reception area and/or close to the isocenter, the basic magnetic field of the basic magnet comprises only one dominant component B0 in the z-direction of the magnetic resonance apparatus. Outside the patient reception area as well, the dominant component of the basic magnetic field and/or a stray field is preferably aligned in the z-direction of the magnetic resonance apparatus. In various embodiments as describe herein, this dominant component of the basic magnetic field may serve as a stator for the magnetic resonance-compatible stepper motor. In this case, it is preferable for the dominant components of the basic magnetic field to be aligned perpendicular to a motor axis of the magnetic resonance-compatible stepper motor. For example, the magnetic resonance-compatible stepper motor may be positioned in the basic magnetic field of the magnetic resonance apparatus in such a manner that the basic magnetic field is aligned perpendicular to a motor axis of the magnetic resonance-compatible stepper motor.

A magnetic resonance-compatible stepper motor should be understood here to mean, for instance, a stepper motor for use with a magnetic resonance apparatus, the magnetic resonance-compatible stepper motor not being designed for imaging. For example, the magnetic resonance-compatible stepper motor may have no imaging components so that interference with magnetic resonance measurement can be advantageously prevented.

The stepper motor may e.g. be designed as an electric motor that comprises the stator and a rotor, e.g. a rotatable motor element. Again, the stator comprises the dominant component of the basic magnetic field and/or a stray field of the basic magnet. The rotor of the stepper motor has at least two rotatable motor elements, namely the at least two rotatably mounted motor coil elements. The two motor coil elements are each arranged so that they can rotate around a motor axis of the stepper motor. A rotational movement of the rotatably mounted and/or rotatably supported motor coil elements may also comprise only a partial rotation and not a complete rotation of the motor coil elements around the motor axis. In an embodiment, the at least two rotatably mounted motor coil elements are mounted in both directions of rotation around the respective motor axis and can perform a rotation in the first direction of rotation or the second direction of rotation depending on a desired direction of movement. For instance, each motor coil element may be configured to perform a rotation between any suitable angular range, such as for example between 5° and a maximum of 20° around the motor axis, approximately 9° around the motor axis, etc. The magnetic resonance-compatible stepper motor may also have a stop element for each of the two motor coil elements, which limits the maximum rotational movement of the motor coil elements.

The at least two rotatably mounted motor coil elements may e.g. comprise at least one coil winding or also a plurality of coil windings, the at least one coil winding or the plurality of coil windings delimiting a coil surface of the at least two rotatably mounted motor coil elements. In an embodiment, the at least two rotatably mounted motor coil elements may have a plurality of windings, so that a large force, e.g. a large Lorentz force, may act on the at least two rotatably mounted motor coil elements to generate a drive torque.

In an embodiment, the at least one coil winding comprises a copper wire. The thinner the copper wire, the more coil windings are mechanically possible. Thus, to generate the Lorentz force required for the movement, it is necessary to find a combination of the number of windings, the wire thickness, and the current strength suitable for the task. In a rotation of the at least two rotatably mounted motor coil elements around the motor axis, an inclination of the coil surface of the at least two rotatably mounted motor coil elements changes with regard to the basic magnetic field and/or the dominant component of the basic magnetic field of the basic magnet.

The two motor coil elements each have a support frame, which may e.g. be made of plastic manufactured in any suitable manner, such as by means of a 3D printing method. The support frames of the individual motor coil elements may each have a rectangular support frame, which has a groove and/or recess in the peripheral direction for the accommodation of the coil winding of copper wire of the respective motor coil element. To stabilize the support frames, these may also have a plurality of cross struts.

In addition, the magnetic resonance-compatible stepper motor may comprise an H-bridge circuit for each motor coil element. A direction of flow of an electric current flowing through the motor coil element can be set by means of the H-bridge circuit. In an embodiment, the individual H-bridge circuits are controlled by a control unit of the magnetic resonance-compatible stepper motor. The direction of flow of the current flowing through the motor coil elements determines the direction of rotation of the respective motor coil element around the motor axis. In an embodiment, each of the motor coil elements performs a partial step of the stepper motor when rotating around the motor axis. The individual motor coil elements, e.g. their H-bridge circuits, are alternately controlled one after the other by means of the control unit until the number of necessary steps has been executed.

The drive shaft of the magnetic resonance-compatible stepper motor may be designed to transmit the drive torque generated by the stepper motor, e.g. the drive torque generated by the motor coil elements, to a further unit. The further unit may for instance comprise the magnetic resonance apparatus or portion thereof. For example, the further unit may comprise a shim apparatus the position of which must be varied between individual measurement steps of an adjustment measurement. This change in position between the individual measurement steps can for instance be carried out vias the magnetic resonance-compatible stepper motor.

The magnetic resonance-compatible stepper motor may comprise at least one gear wheel and/or one gear unit for transmitting the drive torque generated by the individual motor coil elements to the drive shaft. For example, when one of the motor coil elements rotates, this rotational movement is transmitted to a gear wheel and from this gear wheel to the drive shaft.

The magnetic resonance-compatible stepper motor also has a brake unit. The drive shaft can be locked and/or fixed in a defined position by means of the brake unit. By activating the brake unit, a rotation of the drive shaft is also prevented, and the drive shaft remains locked and/or fixed in the current position and no longer performs any movement.

The disclosure can advantageously provide a magnetic resonance-compatible stepper motor that enables the fixing of a position of the drive shaft by means of the stepper motor. Advantageously, this also makes it possible to lock and/or fix the position of a component moved by the stepper motor within the magnetic resonance apparatus. Thus, in addition to providing a drive torque for movement of the component, the stepper motor can also be used to fix the position of the component, and thereby advantageously provide a cost savings and/or obviate additional components. In an embodiment, in this manner a unit for measuring a magnetic field can be positioned within the patient reception area of the magnetic resonance apparatus and repositioned for magnetic field measurements within the patient reception area. The measured results can be used to determine the number and position of shim elements which are to be arranged within the magnet unit for a homogenous magnetic field.

In an advantageous development of the magnetic resonance-compatible stepper motor according to the disclosure, it may be provided that the brake unit has a brake axle, a brake disc mounted so as to be rotatable about the brake axle and at least one brake pad, the brake disc being connected to the drive shaft in a rotating manner, and the at least one brake pad being designed so that it can be pressed and/or pushed down against the brake disc to lock the drive shaft. The rotatably mounted brake disc may e.g. be fixedly arranged on a shaft, e.g. a brake shaft, of the brake unit. The brake shaft may e.g. be likewise arranged so as to rotate around the brake axle. In an embodiment, the brake axle runs centrally through the brake shaft. For instance, the brake disc may be connected to the drive shaft via the brake shaft in a rotating manner, so that when the drive shaft rotates, the brake shaft and thus also the brake disc rotate, provided that no brake force is acting on the brake disc. The brake shaft can be connected to the drive shaft via at least one gear element, for example, a gear wheel. In addition, a direct connection between the drive shaft and the brake shaft is also possible.

The at least one brake pad is pressed against the brake disc to activate a brake force. The at least one brake pad may have a surface on the side facing the brake disc which has high friction, so that a braking process is supported when the at least one brake pad is pressed against the brake disc. The brake unit may also have two brake pads which are arranged on different sides of the brake disc, e.g. on opposite sides of the brake disc, and are pressed against the brake disc from both sides when a braking process is activated. During transmission of drive torque from the drive shaft to a unit of the magnetic resonance apparatus to be moved, the at least one brake pad is arranged at a distance from the brake disc.

This embodiment of the disclosure enables the effective and simple provision of fixation and/or locking of the drive shaft within the magnetic resonance-compatible stepper motor.

In an advantageous development of the magnetic resonance-compatible stepper motor according to the disclosure, it may be provided that the brake unit has at least one brake spring which presses the at least one brake pad against the brake disc. The at least one brake spring may e.g. have a leaf spring. In addition, further embodiments of the at least one brake spring are also possible at any time. For instance, the at least one brake spring may be adjusted in such a manner that a force with which the brake pad is pressed against the brake disc is large enough to lock the drive shaft, and at the same time is smaller than a force with which the brake pad is pushed away from the brake disc during a movement process of the stepper motor. If there are two brake pads, the brake unit may e.g. also have two brake springs, so that each of the two brake pads can be pressed against the brake disc to lock and/or fix the drive shaft. This embodiment of the disclosure enables reliable braking and locking of the drive shaft by means of the brake unit.

In an advantageous development of the magnetic resonance-compatible stepper motor according to the disclosure, it may be provided that the brake unit has at least one adjustment element, a pressing force for pressing the at least one brake pad against the brake disc being adjustable by means of the at least one adjustment element. The at least one adjustment element may e.g. have an adjusting screw. The at least one adjustment element, e.g. the adjusting screw, may act on the at least one brake spring. In an embodiment, depending on the screw position of the adjusting screw, a distance between the brake spring at the position of the adjusting screw and the brake pad can be specified, and thus also a spring force of the brake spring acting on the brake pad. The spring force of the brake spring corresponds to the pressing force with which the brake pad is pressed against the brake disc. The brake force and/or the pressing force may e.g. be set in such a manner that the brake pad prevents the rotation of the brake disc during braking and/or locking and at the same time, during transmission of the drive torque by the stepper motor to another unit, the brake pad can be pushed away from the brake disc. In an embodiment, by means of the adjustment element, e.g. the adjusting screw, a brake force of the brake unit can be adjusted and thus the brake unit adapted to a specific application. In an embodiment, the magnetic resonance-compatible stepper motor has an adjustment element for each brake spring of the brake unit, so that a pressing force can be set for each of the brake springs.

In an advantageous development of the magnetic resonance-compatible stepper motor according to the disclosure, it may be provided that the brake unit has a rotatably mounted brake coil element, the rotatably mounted brake coil element performing a rotational movement when an electric current flows through the rotatably mounted brake coil element, switching a power supply on and off to the rotatably mounted brake coil element resulting in switching between a moving state of the drive shaft and a locked state.

The rotatably mounted brake coil element comprises at least one coil winding or also a plurality of coil windings, the at least one coil winding and/or the plurality of coil windings delimiting a coil surface of the rotatably mounted brake coil element. In an embodiment, the at least one rotatably mounted coil element has a plurality of windings, so that when current flows through the brake coil element and the brake coil element is arranged within the magnetic field of the magnetic resonance apparatus, a large force, e.g. a large Lorentz force, can act on the at least one rotatably mounted coil element and rotate the brake coil element out of its resting state around the coil axis. In an embodiment, the brake coil element comprises a plurality of coil windings made of copper wire. The thinner the copper wire, the more coil windings are mechanically possible. To generate the Lorentz force required for the movement, it is also necessary here to find a combination of the number of windings, the wire thickness, and the current strength which is suitable for the task. In an embodiment, the rotation of the brake coil element may be of any suitable angular range, such as for instance between 5° and a maximum of 20° around the brake axle. The brake unit may also have a stop element that limits the maximum rotational movement of the brake coil element.

In an embodiment, the brake axle of the brake unit is aligned perpendicular to the dominant components of the basic magnetic field. When the rotatably mounted brake coil element rotates around the brake coil axis, the inclination of the coil surface relative to the basic magnetic field and/or the dominant component of the basic magnetic field of the basic magnet changes. In addition, the magnetic resonance-compatible stepper motor comprises an H-bridge circuit for controlling the brake coil element. In an embodiment, the H-bridge circuit of the brake coil element is controlled by the control unit of the magnetic resonance-compatible stepper motor.

The brake coil element has a support frame which may be made of plastic, for example, and manufactured in any suitable manner such as by means of a 3D printing method. The support frame of the brake coil element has a rectangular support frame which has a groove and/or recess in the peripheral direction for the accommodation of the coil winding made of copper wire. To stabilize the support frame, it also has a plurality of cross struts.

The brake coil element is connected to the at least one brake pad in such a manner that, in a first state of the brake coil element, e.g. in a state in which current flows through the brake coil element or in a state in which current does not flow through the brake coil element, a braking effect and/or locking between the at least one brake pad and the brake disc is canceled and transmission of a drive torque by means of the drive shaft is possible. In a second state of the brake coil element, e.g. in the state in which current flows through the brake coil element or in the state in which current does not flow through the brake coil element, on the other hand, a braking effect occurs between the at least one brake pad and the brake disc and thus also a locking of the drive shaft.

This embodiment of the disclosure enables advantageous integration of the brake unit into the magnetic resonance-compatible stepper motor. In an embodiment, the brake unit can also be activated or deactivated in a manner which is compatible with magnetic resonance.

The locked state of the drive shaft comprises a state in which no drive torque can be transmitted. In an embodiment, in this locked state, a brake force always acts on the drive shaft to lock and/or fix the position of the drive shaft. The moving state of the drive shaft, on the other hand, comprises a state, in which a drive torque can be transmitted by means of the drive shaft. In this moving state, a braking effect on the drive shaft is canceled.

In an advantageous development of the magnetic resonance-compatible stepper motor according to the disclosure, it may be provided that the locked state of the drive shaft is achieved when an electric current does not flow through the rotatably mounted brake coil element.

The magnetic resonance-compatible stepper motor may e.g. adapted to magnetic resonance measurement in such a manner that movement of a unit arranged within the magnetic field should only take place during measurement pauses in magnetic resonance measurement by means of the magnetic resonance-compatible stepper motor. This ensures that no electric current flows through the motor coil elements of the stepper motor during individual measurement steps of magnetic resonance measurement that could interfere with magnetic resonance measurement. This allows stable positioning of the additional unit, e.g. the unit which is moved by means of the magnetic resonance-compatible stepper motor, during magnetic resonance measurement. In an embodiment, in the locked state, current flow through the brake coil element and also through the two motor coil elements is prevented, thus also preventing unwanted interference with individual measurement steps of the magnetic resonance measurement.

In an advantageous development of the magnetic resonance-compatible stepper motor according to the disclosure, it may be provided that the rotatably mounted brake coil element has a spacer element which, when an electric current flows through the brake coil element, causes the at least one brake pad to move away from the brake disc. In an embodiment, the spacer element is designed in such a manner that the at least one brake pad is pushed away from the brake disc. The spacer element can be designed as a wedge, for example. In addition, other embodiments of the spacer element are also conceivable. This allows the locking of the drive shaft to be released in a structurally simple manner and the drive torque of the stepper motor to be transmitted again by means of the drive shaft. In an embodiment of the brake unit with two brake pads, the spacer element for releasing the locking of the drive shaft can also be pressed between the two brake pads by the brake coil element. This enables both brake pads to be pushed away from the brake disc by means of a single spacer element.

When an electric current flows through the brake coil element, it performs a tilting movement around a defined tilt angle about the coil axis, the tilting movement ending in a tilted position of the brake coil element and remaining in this tilted position as long as electric current flows through the brake coil element. The spacer element, e.g. the wedge, is arranged on the brake coil element in such a manner that the spacer element can only move the at least one brake pad away from the brake disc in this tilted position of the brake coil element. If no electric current flows through the rotatably mounted brake coil element, the rotatably mounted brake coil element is in an initial position in which there is no contact between the spacer element and the at least one brake pad. In this initial position, braking of the brake disc takes place by means of contact between the at least one brake pad and the brake disc and/or by pressing the at least one brake pad against the brake disc, and thus also locking the drive shaft.

Thus, advantageous locking of the drive shaft can be provided as transmission of drive torque by means of the drive shaft requires the active release of locking and thus of the braking effect of the brake unit. This also ensures that when the brake unit is not in operation, e.g. when no current is flowing through the brake coil element, there is always a braking effect between the at least one brake pad and the brake disc, and the drive shaft is locked.

In an advantageous development of the magnetic resonance-compatible stepper motor according to the disclosure, it may be provided that the brake unit has a guide rail on which the at least one brake pad is guided to move toward or away from the brake disc. This enables a targeted and/or guided movement of the at least one brake pad to achieve a braking effect between the brake pad and the brake disc, or also to eliminate the braking effect.

In an embodiment, the guide rail is arranged in such a manner that contact with the brake disc is prevented. The guide rail may e.g. have a direction of movement for the at least one brake pad, the direction of movement being essentially aligned perpendicular to the brake disc. Depending on the available installation space for the brake unit, the guide rail may also have an orientation differing therefrom. If the brake unit has two brake pads, which are preferably arranged on different, e.g. opposite, sides of the brake disc, the two brake pads can also be guided on a single guide rail. In an embodiment, in such a case, the guide rail is aligned perpendicular to the brake disc so that the two brake pads perform a symmetrically identical movement to activate a braking effect or to eliminate the braking effect of the brake unit.

In an advantageous development of the magnetic resonance-compatible stepper motor according to the disclosure, it may be provided that the at least one brake pad has at least one bearing element. By means of the at least one bearing element, low-friction movement of the at least one brake pad can be achieved when the at least one brake pad is moved. The at least one brake pad may comprise a bearing element for movement on the guide rail. Alternatively or in addition, the at least one brake pad may also have a bearing element for low-friction movement upon contact with the spacer element. In an embodiment, at least one bearing element comprises a plain bearing.

In an advantageous development of the magnetic resonance-compatible stepper motor according to the disclosure, it may be provided that the brake unit has a brake shaft with a brake gear wheel and the drive shaft has a pinion gear drive, the brake gear wheel being rotatably connected to the pinion gear drive. In an embodiment, the brake disc is also arranged on the brake shaft in addition to the brake gear wheel. Advantageously, both the brake gear wheel and the brake disc are fixedly arranged on the brake shaft so that when the brake shaft rotates, the brake gear wheel and the brake disc also rotate. The pinion gear drive is preferably fixedly arranged on the drive shaft so that when the drive shaft rotates, the pinion gear drive also rotates. The brake gear wheel can be directly connected to the pinion gear drive in a rotating manner. In addition, the brake gear wheel can also be connected to the pinion gear drive in a rotating manner via additional gear elements, for example, an additional gear wheel.

As a result of the rotating connection between the pinion gear drive and the brake gear wheel, both the pinion gear drive and the brake gear wheel rotate in a movement mode and/or transmission mode of the stepper motor. In contrast, in the brake mode and/or in the locking mode, movement of the brake gear wheel is blocked, and thus also that of the pinion gear drive. The brake gear wheel is blocked by the brake pads and the brake disc.

This embodiment of the disclosure can provide a structurally simple transmission of a braking effect to the drive shaft, thereby achieving a locking of the drive shaft.

In an advantageous development of the magnetic resonance-compatible stepper motor according to the disclosure, it may be provided that the magnetic resonance-compatible stepper motor has a motor gear, the brake gear wheel being connected in a rotatable manner to the pinion gear drive by means of the motor gear, and a drive torque of the motor coil elements being transmitted to the motor gear when an electric current flows through one of the two motor coil elements. In an embodiment, one of the two motor coil elements is in a drive mode when an electric current flows through the respective motor coil element and generates a drive torque. In this drive mode, a braking effect of the brake unit is also advantageously canceled. Due to the electric current, a Lorentz force acts on the respective motor coil element, which leads to a rotational movement and/or tilting movement of the respective motor coil element around the motor axis of the motor coil element. During this rotational movement and/or tilting movement of the respective motor coil element, the drive torque generated by the rotational movement and/or tilting movement is transmitted to the motor gear. In an initial mode of the motor coil elements, e.g. in a state in which no electric current flows through the motor coil elements, the respective motor coil element is in a rest position and no drive torque is transmitted to the motor gear. In an embodiment, the two motor coil elements are designed in such a manner that no movement or torque is transmitted to the motor gear when moving back from the drive mode to the initial state.

This embodiment of the disclosure enables simple and direct coordination between the brake unit, the two motor coil elements, and the drive shaft.

In an advantageous development of the magnetic resonance-compatible stepper motor according to the disclosure, it may be provided that the magnetic resonance-compatible stepper motor has a step gear and a motor shaft, the step gear and the motor gear being fixedly arranged on the motor shaft and torque and/or drive torque being transmissible from the motor coil elements to the motor gear by means of the step gear. As a result of the fixed arrangement of the step gear and the motor gear on the motor shaft, a rotation of the step gear is transmitted directly to the motor gear via the motor shaft. The motor gear has the task of transmitting a drive torque to the pinion gear drive and thus to the drive shaft, or of transmitting a brake force for locking the drive shaft to the pinion gear drive and thus to the drive shaft. On the other hand, the step gear has the task of transmitting torque and/or drive torque from the motor coil elements to the motor shaft. This embodiment of the disclosure enables the structurally simple transmission of both drive torque to the drive shaft and brake force to the drive shaft.

In an advantageous development of the magnetic resonance-compatible stepper motor according to the disclosure, it may be provided that each of the two motor coil elements has at least one step element, it being possible, by means of the at least one step element, for drive torque to be transmitted to the step gear in only one direction of rotation in a drive mode of the respective motor coil element. In an embodiment, the step element has gearing by means of which drive torque and/or rotational torque can be transmitted from the motor coil element to the step gear. In an embodiment, the gearing of the step element is designed in such a manner that drive torque can only be transmitted in one direction of rotation. For instance, the gearing may be designed in such a manner that when the motor coil element moves back from a tilted state to the initial state, the gearing of the step element slips out of the gearing of the step gear and no further transmission of torque is possible.

In an embodiment, each of the two motor coil elements has two step elements, the first step element being designed to transmit a drive torque in a first direction of rotation and the second step element being designed to transmit a drive torque in a second direction of rotation. In an embodiment, the two step elements are arranged on the motor coil element in such a manner that when an electric current flows in a first current direction, the motor coil element performs a rotational movement and/or tilting movement in the first direction of rotation, and only the first step element can transmit torque and/or drive torque in the first direction of rotation to the step gear. The second step element of the motor coil element is not engaged with the step gear. When an electric current flows in a second current direction so that the motor coil element performs a rotational movement and/or tilting movement in the second direction of rotation, only the second step element can transmit torque and/or drive torque to the step gear in the second direction of rotation while the first step element is not engaged with the step gear.

This enables simple transmission of drive torque from the motor coil elements to the drive shaft. In addition, it ensures that the desired drive torque can be generated and transmitted to the drive shaft by means of targeted control of the motor coil elements. The unwanted transmission of torque resulting from a return movement of the motor coil elements to the initial position can be advantageously prevented by this means.

In an advantageous development of the magnetic resonance-compatible stepper motor according to the disclosure, it may be provided that the magnetic resonance-compatible stepper motor has at least two return elements, each of the return elements being assigned to one of the two motor coil elements and each of the return elements causing a return movement of the respective motor coil element to an initial position when a Lorentz force acting on the respective motor coil element is eliminated. The return elements may each comprise a leaf spring, for example, in a slackened state of the return element, e.g. the leaf spring, the respective motor coil element being arranged in the initial position in which no current flows through the motor coil element. In a drive position, for example in a rotary position and/or a tilted position of the motor coil element on the other hand, the return element, e.g. the leaf spring, is in a tensioned state, which results in a return movement of the motor coil element to the initial position as soon as no more current flows through the motor coil element. In an embodiment, the spring tension of the return element, e.g. the leaf spring, is less than a Lorentz force generated by the current flow. This embodiment of the disclosure enables simple and rapid return of the individual motor coil elements to the initial position after executing a step or a partial step of the stepper motor.

In an embodiment, the magnetic resonance-compatible stepper motor has a further return element which, when the Lorentz force acting on the brake coil element is eliminated, causes the brake coil element to return to an initial position. For instance, the return element assigned to the brake coil element may be identical in design to the return elements for the motor coil elements. Advantageously, the third return element may also be formed by a leaf spring.

In an advantageous development of the magnetic resonance-compatible stepper motor according to the disclosure, it may be provided that the magnetic resonance-compatible stepper motor has a control unit, the control unit being designed to control the individual motor coil elements and the brake coil element accordingly for movement of the drive shaft or locking of the drive shaft. In an embodiment, the control unit may be designed to control a current flow for the individual coil elements, e.g. the two motor coil elements and the brake coil element, in accordance with an operating mode of the stepper motor. For this purpose, each of the coil elements is connected to an H-bridge circuit, the H-bridge circuit allowing the control unit to adjust the current flow and/or current direction for the individual coil elements, e.g. the two motor coil elements and the brake coil element.

The control unit may e.g. comprise at least one computing module and/or a processor. For example, the control unit may comprise a microcontroller. In an embodiment, the control unit is designed to execute computer-readable instructions. For instance, the control unit may comprise a memory unit, computer-readable information being stored on the memory unit, and the control unit being configured to load the computer-readable information from the memory unit and to execute the computer-readable information. In such a manner, the control unit according to the disclosure is configured to control the individual motor coil elements and the brake coil element for movement of the drive shaft or locking of the drive shaft.

The components of the control unit can, for the most part, be designed in the form of software components. In principle, however, these components can also be at least partially implemented in the form of software-supported hardware components, for example, FPGAs or the like, e.g. when particularly fast calculations are required. Likewise, the required interfaces can be designed as software interfaces, for example, if they are only used to transfer data from other software components. However, they can also be designed as hardware interfaces which are controlled by suitable software. Of course, it is also conceivable that a plurality of the components mentioned could be combined in the form of a single software component or software-supported hardware component.

Furthermore, the disclosure is based on a magnetic resonance apparatus with a magnetic resonance-compatible stepper motor, the magnetic resonance-compatible stepper motor comprising a stator, the stator comprising a dominant component of a basic magnetic field of the magnetic resonance apparatus, a drive shaft and at least two rotatably mounted motor coil elements for generating a drive torque of the stepper motor, the drive torque being transmissible by means of the drive shaft. In addition, the magnetic resonance-compatible stepper motor comprises a brake unit which is designed to lock a position of the drive shaft.

The advantages of the magnetic resonance apparatus according to the disclosure essentially correspond to the advantages of the magnetic resonance-compatible stepper motor according to the disclosure, which are described in detail above. The features, advantages, or alternative embodiments mentioned here may also be applied to the other claimed objects and vice versa.

### BRIEF DESCRIPTION OF THE DRAWINGS

Further advantages, features and details of the disclosure will emerge from the exemplary embodiment described hereinafter and with reference to the diagrams.

The diagrams show:

FIG. 1 illustrates an example magnetic resonance apparatus with a magnetic resonance-compatible stepper motor in a diagrammatic view, in accordance with embodiments of the present disclosure;

FIG. 2 illustrates an example magnetic resonance-compatible stepper motor, in accordance with embodiments of the present disclosure;

FIG. 3 illustrates an example motor coil element of the magnetic resonance-compatible stepper motor, in accordance with embodiments of the present disclosure;

FIG. 4 illustrates an example motor coil carrying current in a magnetic field with resulting Lorentz force, in accordance with embodiments of the present disclosure;

FIG. 5 illustrates an example magnetic resonance-compatible stepper motor in a view without coil elements, in accordance with embodiments of the present disclosure;

FIG. 6 illustrates an example drive unit of the stepper motor with the two motor coil elements and a motor gear in a cross-sectional view, in accordance with embodiments of the present disclosure;

FIG. 7 illustrates an example drive unit with the two motor coil elements in a first half-step in clockwise rotation in a cross-sectional view, in accordance with embodiments of the present disclosure;

FIG. 8 illustrates an example drive unit with the two motor coil elements in a second half-step in clockwise rotation in a cross-sectional view, in accordance with embodiments of the present disclosure;

FIG. 9 illustrates an example brake unit of the magnetic resonance-compatible stepper motor, in accordance with embodiments of the present disclosure;

FIG. 10 illustrates an example brake unit in a further view, in accordance with embodiments of the present disclosure; and

FIG. 11 illustrates an example control of the magnetic resonance-compatible stepper motor by means of a control unit, in accordance with embodiments of the present disclosure.

### DETAILED DESCRIPTION

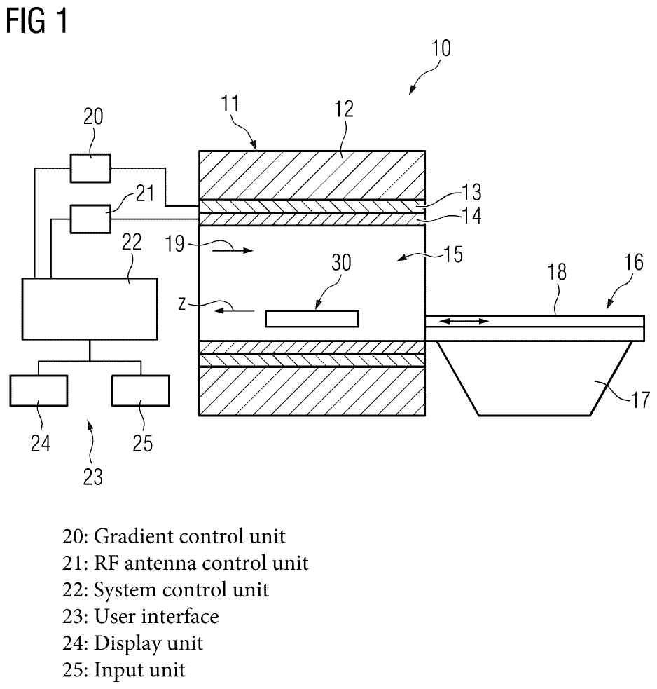

FIG. 1 shows a diagrammatic view of a magnetic resonance apparatus 10. The magnetic resonance apparatus 10 comprises a magnet unit 11 with a basic magnet 12, a gradient coil unit 13, and a high-frequency antenna unit 14, which may alternatively be referred to herein as a radio frequency (RF) antenna unit 14. In addition, the magnetic resonance apparatus 10 has a patient reception area 15 for receiving a patient for a magnetic resonance examination. The patient reception area 15 in the present exemplary embodiment is cylindrical in shape and is surrounded in a circumferential direction by the magnet unit 11, which is cylindrical in shape. In principle, however, a divergent embodiment of the patient reception area 15 is conceivable at any time.

The magnetic resonance apparatus 10 has a patient positioning apparatus 16 for positioning the patient, e.g. an area of the patient to be examined, within the patient reception area 15. The patient positioning apparatus 16 has a base unit 17 and a patient table 18 which can be moved relative to the base unit 17. The patient table 18 is designed to be movable within the patient reception area 15 for positioning of the patient, e.g. the area of the patient to be examined. In an embodiment, the patient table 18 is mounted so that it can be moved in the longitudinal direction of the patient reception area 15 and/or in the z-direction.

The basic magnet 12 of the magnet unit 11 is designed to generate a strong and, in particular, constant basic magnetic field 19. The basic magnet 12 can, for example, be designed as a superconducting basic magnet 12 or also as a permanent magnet. The gradient coil unit 13 of the magnet unit 11 is designed to generate magnetic field gradients which are used for position coding during imaging. The gradient coil unit 13 is controlled by means of a gradient control unit 20 of the magnetic resonance apparatus 10. The RF antenna unit 14 of the magnet unit 11 is designed to excite polarization which is established in the basic magnetic field 19 generated by the basic magnet 12. The RF antenna unit 14 is controlled by an RF antenna control unit 21 of the magnetic resonance apparatus 10 and emits RF magnetic resonance sequences into the patient reception area 15 of the magnetic resonance apparatus 10.

The magnetic resonance apparatus 10 has a system control unit 22 for controlling the basic magnet 12, the gradient control unit 20 and the RF antenna control unit 21. The system control unit 22 controls the magnetic resonance apparatus 10 centrally, such as for example, performing a predetermined imaging gradient-echo sequence. In addition, the system control unit 22 comprises an evaluation unit, not shown in detail, for evaluating medical image data which is captured during the magnetic resonance examination.

Furthermore, the magnetic resonance apparatus 10 comprises a user interface 23 that is connected to the system control unit 22. Control information, such as for example, imaging parameters, and reconstructed magnetic resonance images may e.g. be be displayed on a display unit 24, for example on at least one monitor of the user interface 23 for medical operating personnel. Furthermore, the user interface 23 has an input unit 25, by means of which information and/or parameters can be entered by medical operating personnel during a measurement process.

The magnetic resonance apparatus 10 has a magnetic resonance-compatible stepper motor 30 for moving elements and/or units within the area of the basic magnetic field 19, for example, within the patient reception area 15. For example, the unit to be moved may comprise a shim apparatus the position of which may be varied between individual measurement steps of an adjustment measurement. This change in position between the individual measurement steps can e.g. be performed by means of the magnetic resonance-compatible stepper motor 30. In an embodiment, the drive torque is transmitted to the shim apparatus via a drive shaft of the stepper motor 30. In addition, further transmission elements and/or transmission units, such as for example, a gear unit and/or gears and/or shafts, may be available for transmitting the drive torque to the shim apparatus. In the present exemplary embodiment, the magnetic resonance-compatible stepper motor is arranged within the patient reception area 15.

The magnetic resonance apparatus 10 shown may, of course, comprise further components which magnetic resonance apparatuses 10 usually have. A general mode of operation of a magnetic resonance apparatus 10 is also known to a person skilled in the art, so that a detailed description of the further components is omitted.

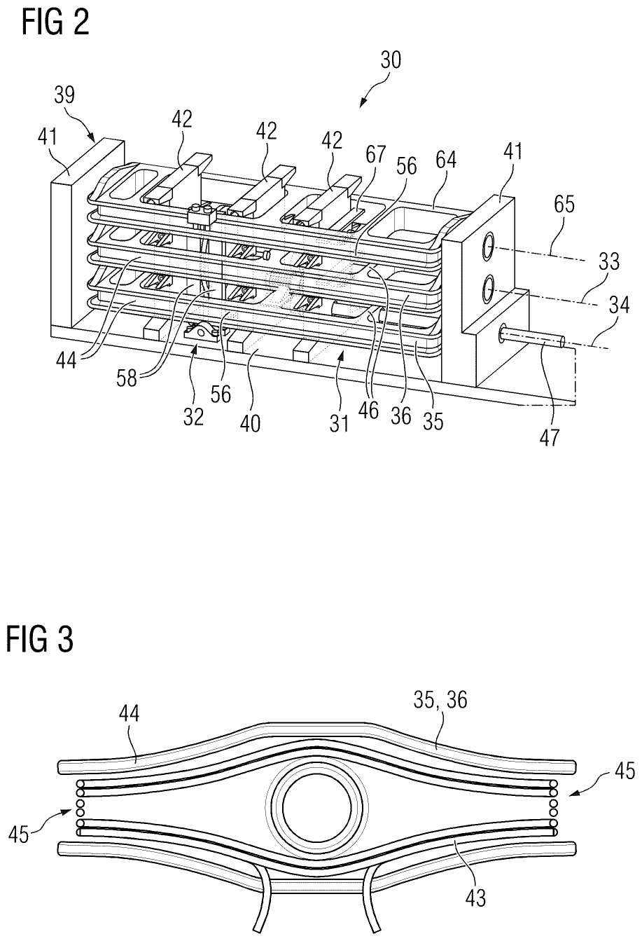

In FIG. 2 to FIG. 11, the magnetic resonance-compatible stepper motor 30 and its mode of operation is described in more detail. The magnetic resonance-compatible stepper motor 30 has a drive unit 31 and a brake unit 32 (FIG. 2).

In an embodiment, the drive unit 31 is designed as an electric motor and comprises a stator and a rotor. The stator comprises the dominant component of the basic magnetic field 19 and/or a stray field of the basic magnet 12. The magnetic resonance-compatible stepper motor 30 is arranged within the basic magnetic field 19 in such a manner that the components of the basic magnetic field 19 acting as the stator, e.g. the dominant components of the basic magnetic field 19, are aligned perpendicular to a motor axis 33, 34 of the stepper motor 30. The rotor of the stepper motor 30 has two rotatably mounted motor coil elements 35, 36. The two motor coil elements 35, 36 are each rotatably mounted around a motor axis 33, 34 of the stepper motor 30 (FIGS. 2, 6, 7, 8). A rotational movement of the rotatably mounted and/or rotatably supported motor coil elements 35, 36 may also comprise only a partial rotation and not a complete rotation around the respective motor axis 33, 34. In an embodiment, the at least two rotatably mounted motor coil elements 35, 36 are rotatably mounted in both directions of rotation 37, 38 around the respective motor axis 33, 34. In an embodiment, a rotation of the motor coil elements 35, 36 comprises any suitable angular range, such as for instance between 5° and a maximum of 20° around the respective motor axis 33, 34, and e.g. approximately 9° around the respective motor axis 33, 34. The motor axes 33, 34 run centrally in the longitudinal direction through the respective motor coil element 35, 36.

In addition, the magnetic resonance-compatible stepper motor 30 has a support structure 39 (FIGS. 2, 5, 9 and 10). The support structure 39 is designed to accommodate and/or store and/or arrange the individual components of the magnetic resonance-compatible stepper motor 30. In an embodiment, the two motor coil elements 35, 36 are rotatably arranged on the support structure 39. The support structure 39 has a base plate 40 and a wall element 41 on each of the two transverse sides, the two transverse sides being aligned perpendicular to the base plate 40 and perpendicular to the longitudinal extension of the base plate 40. In addition, three further support elements 42 are arranged between the two wall elements 41, each of which is aligned parallel to the two wall elements 41. The individual support elements 42 and/or wall elements 41 each have recesses for accommodating bearing elements and/or transmission elements of the stepper motor 30.

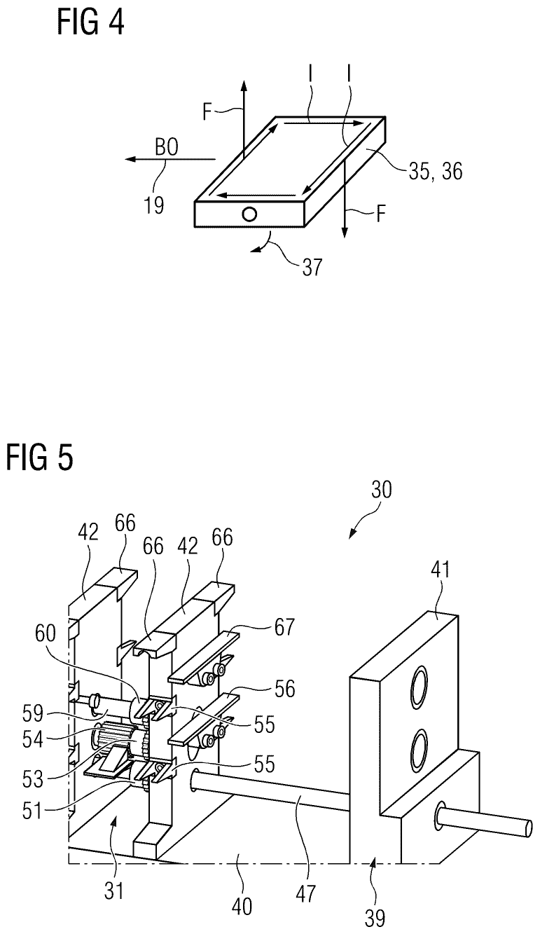

The two rotatably mounted motor coil elements 35, 36 comprise at least one coil winding 43, the at least one coil winding 43 delimiting a coil surface of the rotatably mounted motor coil elements 35, 36 (FIGS. 3 and 4). In the present exemplary embodiment, the two rotatably mounted motor coil elements each have a plurality of coil windings 43, so that a large force, e.g. a large Lorentz force, can act on both rotatably mounted motor coil elements 35, 36 to generate a drive torque. In an embodiment, the coil windings 43 are made from copper wire. When the rotatably mounted motor coil elements 35, 36 are rotated around the motor axis 33, 34, the inclination of the coil surface relative to the basic magnetic field 19 and/or the dominant component of the basic magnetic field 19 of the basic magnet 12 changes (FIG. 3).

The two motor coil elements 35, 36 each have a support frame 44 which is e.g. made of plastic (FIG. 3), for example by means of a 3D printing method. The support frames 44 of the individual motor coil elements 35, 36 each have a rectangular support frame 44 which has a groove and/or recess 45 in the circumferential direction for accommodating a coil winding 43 of the respective motor coil element 35, 36. The support frames 44 have additional cross struts 46 for stabilization. The cross struts 46 of the motor coil elements 35, 36 are arranged in such a manner that, in an arrangement in the support structure 39, the cross struts 46 of the motor coil elements 35, 36 are arranged between the wall elements 41 and/or between support elements 42 of the support structure 39 (FIG. 2).

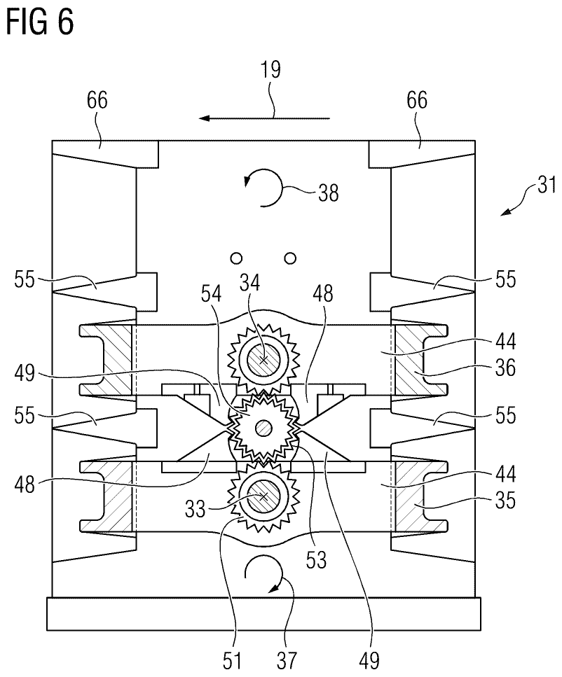

Furthermore, the drive unit 31 has a drive shaft 47 (FIGS. 2, 5 and 9). The drive shaft 47 is designed to transmit the drive torque to the other unit. For the transmission of drive torque and/or rotational torque to the drive shaft 47, each of the two motor coil elements 35, 36 has two step elements 48, 49. The step elements 48, 49 of the individual motor coil elements 35, 36 are shown in the cross-sectional views of FIG. 6 to 8.

Each of the step elements 48, 49 has a gearing by means of which drive torque and/or rotational torque can be transmitted to the drive shaft 47. To transmit the rotational torque and/or drive torque to the drive shaft 47, the drive unit 31 has a pinion gear drive 51 which is fixedly arranged on the drive shaft 47 so that when the drive shaft 47 is rotated, the pinion gear drive 51 also rotates. In addition, the drive unit 31 has a motor shaft 52 with a motor gear 53 and a step gear 54. The motor gear 53 and the step gear 54 are fixedly arranged on the motor shaft 52 so that when the step gear 54 is rotated, the motor shaft 52 and the motor gear 53 are also rotated (FIGS. 2, 5 and 9). The motor gear 53 is designed to transmit drive torque and/or rotational torque to the pinion gear drive 51 and thus to the drive shaft 47.

The step elements 48, 49 are designed in such a manner that rotational torque and/or drive torque of the motor coil elements 35, 36 can only be transmitted to the step gear 54 in one direction of rotation 37, 38 (FIGS. 6, 7 and 8). In an embodiment, the gearing of the step elements 48, 49 is designed in such a manner that rotational torque and/or drive torque can only be transmitted in one direction of rotation 37, 38. In an embodiment, the gearing of the step elements 48, 49 is designed in such a manner that in a return movement of the motor coil elements 35, 36 from a tilted state to the initial state, the gearing slides out of the gearing of the step gear 54 and no further transmission of rotational torque is possible. The step elements 48, 49, the step gear 54, the motor gear 53 and the pinion gear drive 51 are arranged between the first and the second support element 42 of the support structure 39 (FIG. 2).

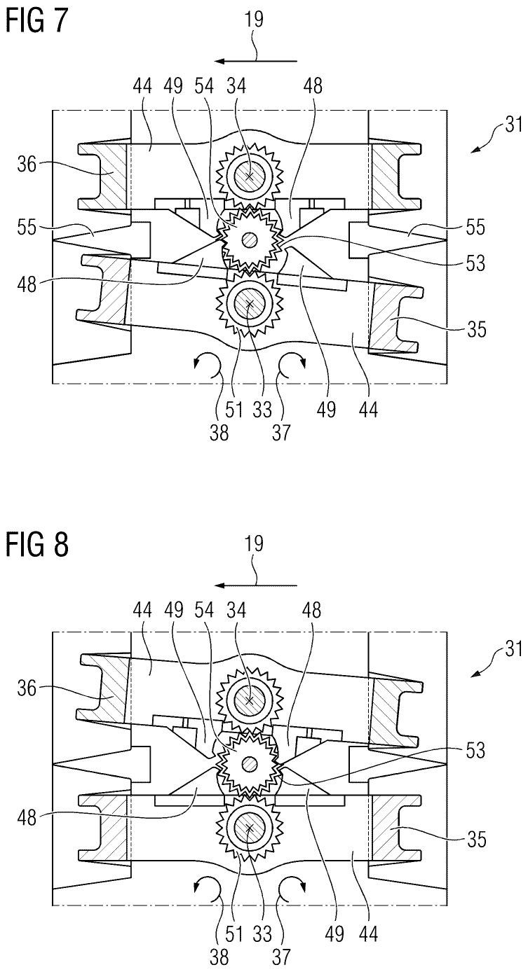

FIGS. 7 and 8 each show a half-step of the stepper motor 30, with the two half-steps together resulting in one whole step of the stepper motor 30. The two half-steps each comprise one rotation of the step gear 54 to the right. In the first half-step (FIG. 7), an electric current flows through the first motor coil element 35 in a first current direction. On account of the arrangement in the basic magnetic field 19 of the magnetic resonance apparatus 10, a Lorentz force is induced in the first motor coil element 35 (FIG. 4), which leads to a rotational movement and/or tilting movement of the first motor coil element 35 around the motor axis 33 in the first direction of rotation 37. On account of this rotational movement and/or tilting movement of the first motor coil element 35, the gearing of the first step element 48 of the first motor coil element 35 engages with the step gear 54 and transmits the rotational movement to the step gear 54. The second step element 49 of the first motor coil element 35, on the other hand, is not engaged with the step gear 54. No current flows through the second motor coil element 36 in the first half-step.

In the second half-step (FIG. 8), an electric current flows through the second motor coil element 36 in the first current direction. On account of the arrangement in the basic magnetic field 19 of the magnetic resonance apparatus 10, a Lorentz force is induced in the second motor coil element 36 (FIG. 4), which leads to a rotational movement and/or tilting movement of the second motor coil element 36 around the motor axis 34 in a first direction of rotation 37. On account of this rotational movement and/or tilting movement of the second motor coil element 36, the gearing of the first step element 48 of the second motor coil element 36 engages with the step gear 54 and transmits the rotational movement to the step gear 54. On the other hand, the second step element 49 of the second motor coil element 36 is not engaged with the step gear 54. No current flows through the first motor coil element 35 in the second half-step.

For the execution of a step in the counter-clockwise direction (not shown in detail in the figures) of the stepper motor 30, an electric current flows in a second current direction through the first motor coil element 35 in the first half-step, so that a rotational movement and/or tilting movement of the first motor coil element 35 around the motor axis 33 is caused in the second direction of rotation 38, e.g. in a counter-clockwise direction. In doing so, the second step element 49, e.g. the gearing of the second step element 49, of the first motor coil element 35 engages with the step gear 54 and transmits the rotational movement to the step gear 54. The first step element 48 of the first motor coil element 35, on the other hand, is not engaged with the step gear 54. No current flows through the second motor coil element 36 in the first half-step. For the second half-step, an electric current flows in a second current direction through the second motor coil element 36, so that a rotational movement and/or tilting movement of the second motor coil element 36 around the motor axis 34 is caused in the second direction of rotation 38, e.g. in a counter-clockwise direction. In the process, the second step element 49, e.g. the gearing of the second step element 49, of the second motor coil element 36 engages with the step gear 54 and transmits the rotational movement to the step gear 54. On the other hand, the first step element 48 of the second motor coil element 36 is not engaged with the step gear 54. No current flows through the first motor coil element 35 in the second half-step.

For a limitation of the rotational movement and/or tilting movement of the two motor coil elements 35, 36, the support unit 39 has a respective stop element 55. The stop elements 55 are arranged on the three support elements 42 and extend laterally outwards from the support elements 42 (FIGS. 2 and 5). The maximum rotational movement and/or tilting movement of the individual motor coil elements 35, 36 is between any suitable angular range such as e.g. between 5° and a maximum of 20° around the motor axis 33, 34 and for instance approximately 9° around the motor axis 33, 34.

In addition, the drive unit 31 has two return elements 56. The two return elements 56 are arranged on the support elements 42 (FIGS. 2, 5 and 9). The return elements 56 are designed to return the motor coil elements 35, 36 to an initial position as soon as no electric current flows through the motor coil elements 35, 36 and thus no Lorentz force acts on the motor coil elements 35, 36. In each case, a return element 56 is assigned to one of the motor coil elements 35, 36, e.g., the first return element 56 is designed to return the first motor coil element 35, and the second return element 56 is designed to return the second motor coil element 36. In the present exemplary embodiment, the two return elements 56 each comprise a leaf spring. When the return elements 56, e.g. the leaf springs, are in a slackened state, the motor coil elements 35, 36 are arranged in an initial position. In this initial position, no electric current flows through the motor coil elements 35, 36 and a Lorentz force does not act on the motor coil elements 35, 36. In a drive position, e.g. in a rotary position and/or a tilted position, of the motor coil elements 35, 36, on the other hand, the return elements 56, e.g. the leaf springs, are in a tensioned state, which leads to a return movement of the motor coil elements 35, 36 to the initial position. In an embodiment, the spring tension of the return elements 56, e.g. the leaf springs, is less than a Lorentz force generated by the current flow.

The brake unit 32 of the stepper motor 30 is designed to lock the drive shaft 47 in position. The brake unit 32 has a brake disc 57 and at least one brake pad 58; in the present exemplary embodiment it has two brake pads 58. The brake disc 57 is connected to the drive shaft 47 in a rotating manner. For this purpose, the brake unit 32 has a brake shaft 59 with a brake gear wheel 60. The brake disc 57 and the brake gear wheel 60 are fixedly arranged on the brake shaft 59 so that when the brake gear wheel 60 rotates, the brake disc 57 also rotates. When the brake disc 57 is locked, the brake gear wheel 60 is therefore also locked. The brake gear wheel 60 is connected to the pinion gear drive 51 via the motor gear 53 and thus to the drive shaft 47. The gearing of the brake gear wheel 60 engages with the gearing of the motor gear 53 and the gearing of the motor gear 53 engages with the gearing of the pinion gear drive 51 to transmit drive torque and/or to transmit brake force and/or locking. The brake gear wheel 60 is arranged, together with the motor gear 53 and the pinion gear drive 51, between the first and the second support element 42 of the support structure 39 (FIG. 2). The remaining brake unit 32, on the other hand, is arranged between the second and the third support element 42 of the support structure 39.

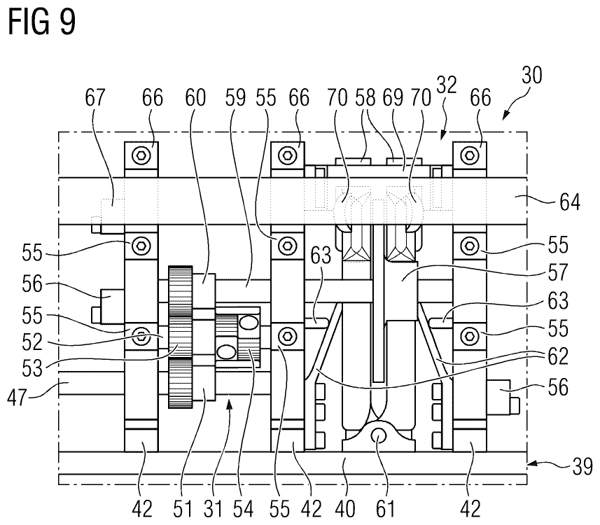

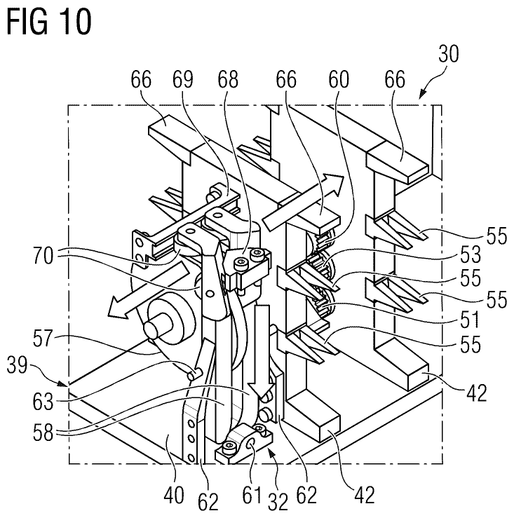

The two brake pads 58 are designed in such a manner that the two brake pads 58 can be pressed against the brake disc 57 to lock the drive shaft 47. For this purpose, the two brake pads 58 are arranged on opposite sides of the brake disc 57 so that a brake force can be exerted on the brake disc 57 from both sides to lock the drive shaft 47. The two brake pads 58 are mounted in a movable manner about a common axis of rotation 61, the two brake pads 58 being able to perform a rotational movement toward the brake disc 57 and a rotational movement away from the brake disc 57 (FIGS. 9 and 10). To perform a rotational movement of the two brake pads 58 toward the brake disc 57 and to generate contact pressure by the two brake pads 58 on the brake disc 57, the brake unit 32 has two brake springs 62. Each brake spring 62 is designed to press against a brake pad 58. The two brake springs 62 are designed and arranged in such a manner that they press against the respective brake pad 58 on the side facing away from the brake disc 57.

The brake unit 32 has two adjustment elements 63 (FIGS. 9 and 10) for adjusting a brake force and/or a pressing force for pressing the brake pads 58 against the brake disc 57. In the present exemplary embodiment, the two adjustment elements 63 are designed as adjusting screws which adjust the preload and/or the distance between the brake springs 62 and the brake pads 58. The first adjusting screw is screwed against the second support element 42 and the second adjusting screw is screwed against the third support element 42. The pressing force with which the two brake pads 58 press against the brake disc 57 to lock the drive shaft 47 must be large enough to fix the brake disc 57 and also the drive shaft 47 in their position, and at the same time be less than the force with which the brake pads 58 are pushed away from the brake disc 57 in order to transmit drive torque to the next unit.

To adjust a brake mode and a transmission mode, the brake unit 32 has a rotatably mounted brake coil element 64, the brake coil element 64 being rotatably mounted around a brake axle 65 of the brake unit 32 (FIG. 9). The mode of operation of the rotatably mounted brake coil element 64 is analogous to the mode of operation of the rotatably mounted motor coil elements 35, 36. When an electric current flows through the brake coil element 64, the brake coil element 64 performs a rotational movement and/or a tilting movement around the brake axle 65. As long as an electric current flows through the brake coil element 64, the brake coil element 64 remains in a tilted position. In order to achieve a defined tilted position, the brake unit 32 likewise has a stop element 66 which is designed analogously to the stop elements 55 of the drive unit 31 (FIG. 9). In addition, the brake unit 32 also has a return element 67, which is also designed as a leaf spring (FIG. 9). The mode of operation of the return element 67 is analogous to that of the return elements 56 of the drive unit 31. As soon as no more electric current flows through the brake coil element 64, the return element 67 causes the brake coil element 64 to return to its initial position.

Switching the power supply of the rotatably mounted brake coil element 64 on and off and thus switching the current flow through the rotatably mounted brake coil element 64 on and off, causes the drive shaft 47 to switch between a locked state and a moving state. The locked state and/or a braking state of the drive shaft 47 is achieved when no electric current flows through the brake coil element 64. In contrast, when an electric current flows through the brake coil element 64 so that the brake coil element 64 performs a rotational movement and/or a tilting movement into the tilted position, the locked state is released, and a drive torque can again be transmitted by means of the drive shaft 47.

The brake coil element 64 has a spacer element 68 to release the locked state. In the present exemplary embodiment, the spacer element 68 is designed as a wedge (FIG. 10). In the tilted position of the brake coil element 64, the spacer element 68, e.g. the wedge, is pushed between the two brake pads 58, and thus presses the two brake pads 58 away from the brake disc 57. For a defined and/or targeted movement of the brake pads 58 toward or away from the brake disc 57, the brake unit 32 has a guide rail 69. The two brake pads 58 are guided on this guide rail 69 during movement. The guide rail 69 is aligned perpendicular to the brake disc 57.

For low-friction movement of the two brake pads 58 on the guide rail 69 or with regard to the spacer element 68, e.g. the wedge, the two brake pads 58 each have at least one bearing element 70. In the present exemplary embodiment, the two brake pads 58 each have two bearing elements 70 (FIGS. 9 and 10). The individual bearing elements 70 each comprise a plain bearing or a ceramic ball bearing. A first bearing element 70, e.g. a first plain bearing or a ceramic ball bearing of each of the brake pads 58 is designed for low-friction movement in the guide rail 69. A second bearing element 70, e.g. a first plain bearing or a ceramic ball bearing of each of the brake pads 58 is designed for low-friction movement with regard to the spacer element 68, e.g. the wedge.

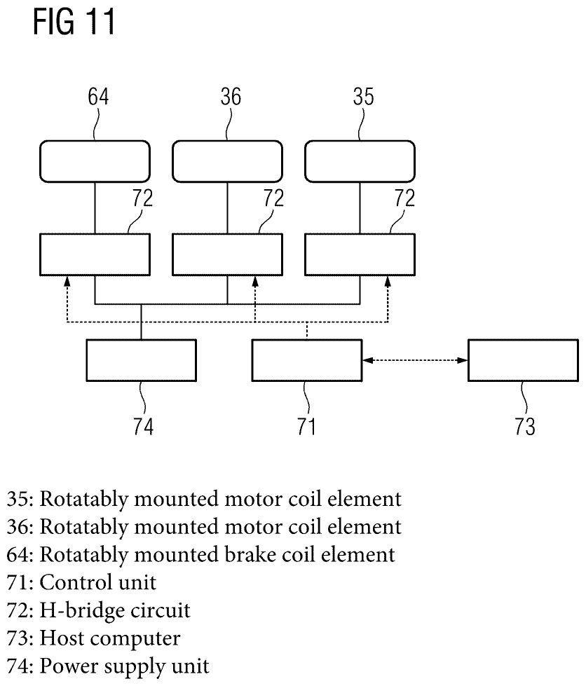

The magnetic resonance-compatible stepper motor 30 has a control unit 71 (also referred to herein as a controller, processing circuitry, or a control computer) for control (FIG. 11). The control unit 71 is designed to control the current flow and/or the current direction in the individual motor coil elements 35, 36 and the brake coil element 64. For this purpose, the magnetic resonance-compatible stepper motor 30 has an H-bridge circuit 72 for each motor coil element 35, 36 and for the brake coil element 64. The direction of flow of an electric current flowing through the motor coil elements 35, 36 can be adjusted by means of the H-bridge circuit 72. The control unit 71 may comprise a microcontroller which receives control commands from a host computer 73 and forwards them to the corresponding H-bridge circuits 72. The motor coil elements 35, 36 and the brake coil element 64 are connected to a power supply unit 74 via the H-bridge circuits 72.

For movement of the drive shaft 47 in a first direction, the control may be implemented for instance as follows:

In a first step, the brake and/or the lock is released. In doing so, the brake coil element 64 is switched to current flowing in the “+” direction. For the first half-step in the desired direction of rotation 37, the first motor coil element 35 is then switched to a current flowing in the “+” direction. No current flows through the second motor coil element 36 and it is switched to “0”. Current continues to flow through the brake coil element 64 in the “+” direction in this first half-step. For the second half-step, no current flows through the first motor coil element 35 and it is switched to “0”. The second motor coil element 36 is switched with a current in the “+” direction. Current continues to flow through the brake coil element 64 in the “+” direction. The first half-step and the second half-step are repeated by the control unit 71 until the desired number of steps has been reached. To activate the brake, the two motor coil elements 35, 36 and the brake coil element 64 are switched to “0” and no current flows through any of the coil elements.

The control system provides the following steps for movement of the drive shaft 47 in the opposite direction:

In a first step, the brake and/or the lock is released. The brake coil element 64 is switched to current flowing in the “+” direction. For the first half-step, the first motor coil element 35 is then switched to a current in the “−” direction. No current flows through the second motor coil element 36 and it is switched to “0”. Current continues to flow through the brake coil element 64 in the “+” direction. For the second half-step, no current flows through the first motor coil element 35 and it is switched to “0”. The second motor coil element 36 is switched with a current in the “−” direction. Current continues to flow through the brake coil element 64 in the “+” direction. The first half-step and the second half-step are repeated by the control unit 71 until the desired number of steps has been reached. To activate the brake, the two motor coil elements 35, 36 and the brake coil element 64 are switched to “0” and no current flows through any of the coil elements.

Although the disclosure has been illustrated and described in detail by the preferred exemplary embodiment, the disclosure is not limited by the disclosed examples, and other variations can be derived therefrom by a person skilled in the art without departing from the scope of the disclosure.

The various components described herein may be referred to as “devices” or “units.” As noted above, such components may be implemented via any suitable combination of hardware and/or software components as applicable and/or known to achieve the intended respective functionality. This may include mechanical and/or electrical components, processors, processing circuitry, or other suitable hardware components configured to execute instructions or computer programs that are stored on a suitable computer readable medium. Regardless of the particular implementation, such devices and units, as applicable and relevant, may alternatively be referred to herein as “circuitry,” “processors,” or “processing circuitry.”

In this text, independent of the grammatical term usage, individuals with male, female or other gender identities are included within the term.

What is claimed is:

1. A magnetic resonance-compatible stepper motor for use in a medical magnetic resonance apparatus, the stepper motor comprising:
a drive shaft;
two rotatably mounted motor coil elements configured to generate a drive torque of the stepper motor ;and
a brake unit configured to lock a position of the drive shaft,
wherein the drive torque is transmittable via the drive shaft, and
wherein the magnetic resonance-compatible stepper motor is configured to use a basic magnetic field of the magnetic resonance apparatus as a stator of the stepper motor.

2. The stepper motor as claimed in claim 1, wherein:
the brake unit comprises a brake axle and a brake disc mounted so as to be rotatable about the brake axle and a brake pad,
the brake disc is connected to the drive shaft in a rotating manner, and
the brake pad is configured to be pressed against the brake disc to lock the drive shaft.

3. The stepper motor as claimed in claim 2, wherein the brake unit comprises a brake spring that presses the brake pad against the brake disc.

4. The stepper motor as claimed in claim 2, wherein the brake unit comprises an adjustment element, and
wherein a pressing force for pressing the brake pad against the brake disc is adjustable via the adjustment element.

5. The stepper motor as claimed in claim 1, wherein:
the brake unit comprises a rotatably mounted brake coil element,
the rotatably mounted brake coil element is configured to perform a rotational movement when an electric current flows through the rotatably mounted brake coil element, and
switching power supplied to the rotatably mounted brake coil element on and off results in switching between a moving state and a locked state of the drive shaft, respectively.

6. The stepper motor as claimed in claim 5, wherein the rotatably mounted brake coil element comprises a spacer element that causes, when an electric current flows through the rotatably mounted brake coil element, a movement of a brake pad away from a brake disc, the brake pad and brake disc being associated with the brake unit.

7. The stepper motor as claimed in claim 2, wherein the brake unit comprises a guide rail on which the brake pad is guided for a movement toward or away from the brake disc.

8. The stepper motor as claimed in claim 2, wherein the brake pad comprises a bearing element.

9. The stepper motor as claimed in claim 1, wherein:
the brake unit comprises a brake shaft with a brake gear wheel,
the drive shaft comprises a pinion gear drive, and
the brake gear wheel is rotatably connected to the pinion gear drive.

10. The stepper motor as claimed in claim 9, further comprising:
a motor gear,
wherein the brake gear wheel is rotatably connected to the pinion gear drive via the motor gear, and
wherein a drive torque of one of the two motor coil elements is transmitted to the motor gear when an electric current flows through that motor coil element.

11. The stepper motor as claimed in claim 10, further comprising:
a step gear; and
a motor shaft,
wherein the step gear and the motor gear are securely arranged on the motor shaft, and
wherein torque is transmittable from the two motor coil elements to the motor gear via the step gear.

12. The stepper motor as claimed in claim 11, wherein each one of the two motor coil elements comprises a step element, and
wherein a drive torque is transmittable to the step gear via the step element in one direction of rotation when the respective motor coil element is in a drive mode.

13. The stepper motor as claimed in claim 1, further comprising:
two return elements,
wherein each one of the two return elements is assigned to a respective one of the two motor coil elements, and
wherein each one of the return elements causes a return movement of the respective one of the two motor coil elements to an initial position when a Lorentz force acting on the respective motor coil element is removed.

14. The stepper motor as claimed in claim 1, further comprising:
a controller configured to control individual ones of the two motor coil elements and a brake coil element associated with the brake unit to facilitate movement of the drive shaft or locking of the drive shaft.

15. A magnetic resonance apparatus, comprising:
a patient reception area configured to receive a patient for a magnetic resonance examination; and
a magnetic resonance-compatible stepper motor disposed within the patient reception area, the stepper motor comprising:
a drive shaft;
two rotatably mounted motor coil elements configured to generate a drive torque of the stepper motor; and
a brake unit configured to lock a position of the drive shaft,
wherein the drive torque is transmittable via the drive shaft, and
wherein the magnetic resonance-compatible stepper motor is configured to use a basic magnetic field of the magnetic resonance apparatus as a stator of the stepper motor.
